(19) United States
(12) Patent Application Publication
(10) Pub. No.: US 2015/0280156 A1
(43) Pub. Date: Oct. 1, 2015

(54) TRANSPARENT ELECTRODE AND ASSOCIATED PRODUCTION METHOD

(71) Applicant: HUTCHINSON, Paris (FR)

(72) Inventors: Jérémie Jacquemond, Montargis (FR); Stéphane Roger, Saint Maurice sur Fessard (FR); Bruno Dufour, Champagne sur Seine (FR); Philippe Sonntag, Avon (FR)

(73) Assignee: HUTCHINSON, Paris (FR)

(21) Appl. No.: 14/433,313

(22) PCT Filed: Oct. 2, 2013
(86) PCT No.: PCT/EP2013/070593

§ 371 Date: Apr. 2, 2015

(30) Foreign Application Priority Data
Oct. 3, 2012 (FR) 1259358

(51) Int. Cl. H01L 51/44; H01L 51/52

(52) U.S. Cl. CPC H01L 51/442; H01L 51/5215; H01L 51/5234; H01L 51/0037

(57) ABSTRACT

The present invention relates to a multilayer conductive transparent electrode comprising:
a substrate layer,
a conductive layer comprising:
   at least one optionally substituted polythiophene conductive polymer, and
   a percolating network of metal nanofilaments,
      the conductive layer being in direct contact with the substrate layer and the conductive layer also comprising at least one hydrophobic adhesive polymer or adhesive copolymer. The invention also relates to the process for manufacturing such a multilayer conductive transparent electrode.

The present invention relates to a conductive transparent electrode and also to the process for manufacturing the same, in the general field of organic electronics.

Conductive transparent electrodes having both high transmittance and electrical conductivity properties are currently the subject of considerable development in the field of electronic equipment, this type of electrode being increasingly used for devices such as photovoltaic cells, liquid-crystal screens, organic light-emitting diodes (OLED) or polymeric light-emitting diodes (PLED) and touch screens.

In order to obtain conductive transparent electrodes which have high transmittance and electrical conductivity properties, it is known practice to have a multilayer conductive transparent electrode comprising in a first stage a substrate layer on which are deposited an adhesion layer, a percolating network of metal nanofilaments and an encapsulation layer made of conductive polymer, for instance a poly(3,4-ethylenedioxythiophene) (PEDOT) and sodium poly(styrene sulfonate) (PSS) mixture, forming what is known as PEDOT:PSS.

Patent application US2009/129004 proposes a multilayer transparent electrode which makes it possible to achieve all the desired properties, especially in terms of transmittance and surface resistivity. However, such an electrode has a complex architecture, with a substrate, an adhesion layer, a layer consisting of metal nanofilaments, an electrical homogenization layer comprising carbon nanotubes and a conductive polymer. This addition of layers entails a substantial cost for the process. Furthermore, the need to use an adhesion layer entails a loss of optical transmission. Finally, the homogenization layer is based on carbon nanotubes, which pose dispersion problems.

It is thus desirable to develop a conductive transparent electrode comprising a minimum of layers, and not comprising any carbon nanotubes.

One of the aims of the invention is thus to at least partially overcome the prior art drawbacks and to propose a multilayer conductive transparent electrode which has high transmittance and electrical conductivity properties, and also a process for manufacturing the same.

The present invention thus relates to a multilayer conductive transparent electrode, comprising:
a substrate layer,
a conductive layer comprising:
   at least one optionally substituted polythiophene conductive polymer, and
   a percolating network of metal nanofilaments,
      the conductive layer being in direct contact with the substrate layer and the conductive layer also comprising at least one hydrophobic adhesive polymer or adhesive copolymer.

The multilayer conductive transparent electrode according to the invention satisfies the following requirements and properties:
a surface electrical resistance R of less than 100 Ω/□,
a mean transmittance Tₘₑₐₙ in the visible spectrum of greater than or equal to 75%,
direct adhesion to the substrate, and
absence of optical defects.

According to one aspect of the invention, the conductive layer also comprises at least one additional polymer.

According to another aspect of the invention, the additional polymer is polyvinylpyrrolidone.

According to another aspect of the invention, the multilayer conductive transparent electrode has a mean transmittance in the visible spectrum of greater than or equal to 75%.

According to another aspect of the invention, the multilayer conductive transparent electrode has a surface resistance of less than 100 Ω/□.

According to another aspect of the invention, the substrate is chosen from glass and transparent flexible polymers.

According to another aspect of the invention, the metal nanofilaments are nanofilaments of noble metals.

According to another aspect of the invention, the metal nanofilaments are nanofilaments of non-noble metals.

According to another aspect of the invention, the adhesive polymer or adhesive copolymer is chosen from polyvinyl acetate polymers or acrylonitrile-acrylic ester copolymers.

The invention also relates to a process for manufacturing a multilayer conductive transparent electrode, comprising the following steps:
a step of preparing and applying a conductive layer directly onto a substrate layer, said conductive layer comprising:
   at least one optionally substituted polythiophene conductive polymer,
   a percolating network of metal nanofilaments, and
   at least one hydrophobic adhesive polymer or adhesive copolymer,
      a step of crosslinking the conductive layer.

According to one aspect of the process according to the invention, the step of preparing and applying a conductive layer directly onto the substrate layer comprises the following substeps:
a substep of preparing a composition forming the conductive layer comprising:
   a dispersion or suspension of at least one optionally substituted polythiophene conductive polymer,
   at least one hydrophobic adhesive polymer or adhesive copolymer,
a substep of adding a suspension of metal nanofilaments to the composition forming the conductive layer, and
a substep of applying the mixture directly onto the substrate layer.

According to another aspect of the process according to the invention, the step of preparing and applying a conductive layer directly onto the substrate layer comprises the following substeps:
a substep of preparing a composition forming the conductive layer comprising:
   a dispersion or suspension of at least one optionally substituted polythiophene conductive polymer,
   at least one hydrophobic adhesive polymer or adhesive copolymer,
a substep of applying a suspension of metal nanofilaments directly onto the substrate layer so as to form a percolating network of metal nanofilaments,
a substep of applying the composition forming the conductive layer onto the percolating network of metal nanofilaments.

According to another aspect of the process according to the invention, the composition forming the conductive layer also comprises at least one additional polymer.

According to another aspect of the process according to the invention, the additional polymer is polyvinylpyrrolidone.

According to another aspect of the process according to the invention, the substrate of the substrate layer is chosen from glass and transparent flexible polymers.

According to another aspect of the process according to the invention, the metal nanofilaments are nanofilaments of noble metals.

According to another aspect of the process according to the invention, the metal nanofilaments are nanofilaments of non-noble metals.

According to another aspect of the process according to the invention, the adhesive polymer or adhesive copolymer is chosen from polyvinyl acetate polymers or acrylonitrile-acrylic ester copolymers.

Other characteristics and advantages of the invention will emerge more clearly on reading the description that follows, which is given as a nonlimiting illustrative example, and of the attached drawings, among which:

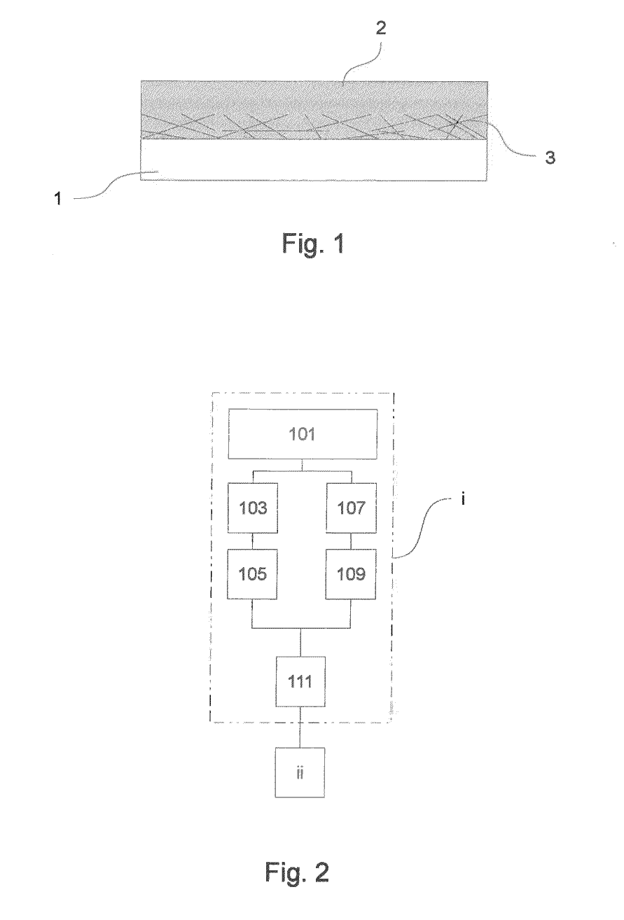

FIG. 1 is a schematic representation in cross section of the various layers of the multilayer conductive transparent electrode,

FIG. 2 is a flow diagram of the various steps of the manufacturing process according to the invention.

The present invention relates to a multilayer conductive transparent electrode, illustrated in FIG. 1. This type of electrode preferably has a thickness of between 0.05 μm and 20 μm.

Said multilayer conductive transparent electrode comprises:
a substrate layer 1, and
a conductive layer 2 in direct contact with the substrate layer 1.

In order to preserve the transparent nature of the electrode, the substrate layer 1 must be transparent. It may be flexible or rigid and advantageously chosen from glass in the case where it must be rigid, or alternatively chosen from transparent flexible polymers such as polyethylene terephthalate (PET), polyethylene naphthalate (PEN), polyether sulfone (PES), polycarbonate (PC), polysulfone (PSU), phenolic resins, epoxy resins, polyester resins, polyimide resins, polyetherester resins, polyetheramide resins, poly(vinyl acetate), cellulose nitrate, cellulose acetate, polystyrene, polyolefins, polyamide, aliphatic polyurethanes, polyacrylonitrile, polytetrafluoroethylene (PTFE), polymethyl methacrylate (PMMA), polyarylate, polyetherimides, polyether ketones (PEK), polyether ether ketones (PEEK) and polyvinylidene fluoride (PVDF), the flexible polymers that are the most preferred being polyethylene terephthalate (PET), polyethylene naphthalate (PEN) and polyether sulfone (PES).

The conductive layer 2 comprises:

(a) at least one optionally substituted polythiophene conductive polymer,

(b) at least one adhesive polymer or adhesive copolymer,

(c) a percolating network of metal nanofilaments 3.

The conductive layer 2 may also comprise:

(d) at least one additional polymer.

The conductive polymer (a) is a polythiophene, the latter being one of the most thermally and electronically stable polymers. A preferred conductive polymer is poly(3,4-ethylenedioxythiophene)-poly(styrenesulfonate) (PEDOT:PSS), the latter being stable to light and heat, easy to disperse in water, and not having any environmental drawbacks.

The adhesive polymer or adhesive copolymer (b) is preferentially a hydrophobic compound and may be chosen from polyvinyl acetate polymers or acrylonitrile-acrylic ester copolymers. The adhesive polymer or adhesive copolymer (b) especially allows better adhesion between the percolating network of metal nanofilaments 3 and the conductive polymer (a).

The percolating network of metal nanofilaments 3 is preferentially composed of nanofilaments of a noble metal such as sliver, gold or platinum. The percolating network of metal nanofilaments 3 may also be composed of nanofilaments of a non-noble metal such as copper.

The percolating network of metal nanofilaments 3 may consist of one or more superposed layers of metal nanofilaments 3 thus forming a conductive percolating network and may have a density of metal nanofilaments 3 of between 0.01 μg/cm² and 1 mg/cm².

The additional polymer (d) is chosen from polyvinyl alcohols (PVOH), polyvinylpyrrolidones (PVP), polyethylene glycols or alternatively ethers and esters of cellulose or other polysaccharides. This additional polymer (d) is a viscosity-enhancing agent and aids the formation of a good-quality film during the application of the conductive layer 2 to the substrate layer 1.

The conductive layer 2 may comprise each of the constituents (a), (b), (c) and (d) in the following weight proportions (for a total of 100% by weight):
(a) from 10% to 65% by weight of at least one optionally substituted polythiophene conductive polymer,
(b) from 20% to 85% by weight of at least one adhesive polymer or adhesive copolymer,
(c) from 5% to 40% by weight of metal nanofilaments 3,
(d) and from 0 to 15% by weight of at least one additional polymer.

The multilayer conductive transparent electrode according to the invention thus comprises:
a surface electrical resistance R of less than 100 Ω/□,
a mean transmittance Tₘₑₐₙ in the visible spectrum of greater than or equal to 75%,
direct adhesion to the substrate, and
absence of optical defects.

The present invention also relates to a process for manufacturing a multilayer conductive transparent electrode, comprising the following steps:

The steps of the manufacturing process are illustrated in the flow diagram of FIG. 2.

i) Preparation of a Conductive Layer 2 on a Substrate Layer 1

A conductive layer 2 is prepared on a substrate layer 1 in this step i.

In order to preserve the transparent nature of the electrode, the substrate layer 1 must be transparent. It may be flexible or rigid and advantageously chosen from glass in the case where it must be rigid, or alternatively chosen from transparent flexible polymers such as polyethylene terephthalate (PET), polyethylene naphthalate (PEN), polyether sulfone (PES), polycarbonate (PC), polysulfone (PSU), phenolic resins, epoxy resins, polyester resins, polyimide resins, polyetherester resins, polyetheramide resins, poly(vinyl acetate), cellulose nitrate, cellulose acetate, polystyrene, polyolefins, polyamide, aliphatic polyurethanes, polyacrylonitrile, polytetrafluoroethylene (PTFE), polymethyl methacrylate (PMMA), polyarylate, polyetherimides, polyether ketones (PEK), polyether ether ketones (PEEK) and polyvinylidene fluoride (PVDF), the flexible polymers that are the most preferred being polyethylene terephthalate (PET), polyethylene naphthalate (PEN) and polyether sulfone (PES).

The conductive layer 2 comprises:

(a) at least one optionally substituted polythiophene conductive polymer,

(b) at least one hydrophobic adhesive polymer or adhesive copolymer,

(c) a percolating network of metal nanofilaments 3.

The conductive layer 2 may also comprise:

(d) at least one additional polymer.

The conductive polymer (a) is a polythiophene, the latter being one of the most thermally and electronically stable polymers. A preferred conductive polymer is poly(3,4-ethylenedioxythiophene)-poly(styrenesulfonate) (PEDOT:PSS), the latter being stable to light and heat, easy to disperse in water, and not having any environmental drawbacks.

The adhesive polymer or adhesive copolymer (b) is a hydrophobic compound and is chosen from polyvinyl acetate polymers or acrylonitrile-acrylic ester copolymers. The adhesive polymer or adhesive copolymer (b) especially allows better adhesion between the percolating network of metal nanofilaments 3 and the conductive polymer (a).

Since the adhesive polymer or adhesive copolymer (b) is a hydrophobic compound, it forms a suspension in the solvent and this allows better dispersion of the latter within the solution.

The additional polymer (d) is chosen from polyvinyl alcohols (PVOH), polyvinylpyrrolidones (PVP), polyethylene glycols or alternatively ethers and esters of cellulose or of other polysaccharides.

A first substep 101 of step i) for preparing the conductive layer 2 is thus the preparation of a composition forming the conductive layer 2. For this, the components (a), (b) and optionally (d) are mixed together in order to form said composition.

To do this, the conductive polymer (a) may be in the form of a dispersion or a suspension in water and/or in a solvent, said solvent preferably being a polar organic solvent chosen from dimethyl sulfoxide (DMSO), N-methyl-2-pyrrolidone (NMP), ethylene glycol, tetrahydrofuran (THF), dimethyl acetate (DMAc), dimethylformamide (DMF), the conductive polymer (b) preferably being in dispersion or in suspension in water, dimethyl sulfoxide (DMSO) or ethylene glycol.

The additional polymer (d) may itself be in the form of a dispersion or a suspension in water and/or in a solvent, said solvent preferably being an organic solvent chosen from dimethylsulfoxide (DMSO), N-methyl-2-pyrrolidone (NMP), ethylene glycol, tetrahydrofuran (THF), dimethyl acetate (DMAc) or dimethylformamide (DMF).

The preparation of the composition forming the conductive layer may comprise successive steps of mixing and stirring, for example using a magnetic stirrer as illustrated in the composition examples of examples A to D described hereinbelow in the experimental section.

According to a first embodiment of the manufacturing process according to the invention, the metal nanofilaments 3 in suspension form are added directly, during a substep 103 to the composition forming the conductive layer 2. These metal nanofilaments 3, for example consisting of noble metals, such as silver, gold or platinum, are preferentially in solution in isopropanol (IPA).

The composition forming the conductive layer 2 is then deposited during a substep 105 onto the substrate layer 1, according to any method known to those skilled in the art, the techniques most commonly used being spray coating, inkjet coating, dip coating, film-spreader coating, spin coating, coating by impregnation, slot-die coating, scraper coating, or flexographic coating, and so as to obtain a film comprising a percolating network of metal nanofilaments 3.

According to a second embodiment of the manufacturing process according to the invention, the metal nanofilaments 3 are deposited beforehand, during a substep 107, directly onto the substrate layer 1 so as to form a percolating network of metal nanofilaments 3.

To do this, a suspension of metal nanofilaments 3 is applied directly to the substrate layer 1.

In order to form the suspension of metal nanofilaments 3, said metal nanofilaments 3 are predispersed in a readily evaporable organic solvent (for example ethanol) or dispersed in an aqueous medium in the presence of a surfactant (preferably an ionic conductor). It is this suspension of metal nanofilaments 3 to a solvent, for example isopropanol (IPA), which is applied to the substrate layer 1.

The metal nanofilaments 3 may consist of noble metals, for instance silver, gold or platinum. The metal nanofilaments 3 may also consist of non-noble metals, for instance copper.

The suspension of metal nanofilaments 3 may be deposited on the substrate layer 1 according to any method known to those skilled in the art, the techniques most commonly used being spray coating, inkjet coating, dip coating, film-spreader coating, spin coating, coating by impregnation, slot-die coating, scraper coating, or flexographic coating.

The quality of the dispersion of the metal nanofilaments 3 in the suspension conditions the quality of the percolating network formed after evaporation. For example, the concentration of the dispersion may be between 0.01 wt % and 10 wt %, preferably between 0.1 wt % and 2 wt %, in the case of a percolating network prepared in a single pass.

The quality of the percolating network formed is also defined by the density of metal nanofilaments 3 present in the percolating network, this density being between 0.01 μg/cm² and 1 mg/cm², and preferably between 0.01 μg/cm² and 10 μg/cm².

The final percolating network of metal nanofilaments 3 may consist of several superposed layers of metal nanofilaments 3. For this, it suffices to repeat the deposition steps as many tunes as it is desired to obtain layers of metal nanofilaments 3. For example, the percolating network of metal nanofilaments 3 may comprise from 1 to 800 superposed layers, preferably less than 100 layers, with a dispersion of metal nanofilaments 3 at 0.1 wt %.

Following substep 107 of deposition of the percolating network of metal nanofilaments 3 onto the substrate layer 1, the composition forming the conductive layer 2 is applied to the percolating network of metal nanofilaments 3, during a substep 109, according to any method known to those skilled in the art, the techniques most commonly used being spray coating, inkjet coating, dip coating, film-spreader coating, spin coating, coating by impregnation, slot-die coating, scraper coating, or flexographic coating, and so as to obtain a film whose thickness may be between 50 nm and 15 μm and comprising a percolating network of metal nanofilaments 3.

A substep 111 of drying is then performed so as to evaporate off the various solvents from the conductive layer 2. This drying step 111 may be performed at a temperature of between 20 and 50° C. in air for 1 to 45 minutes.

ii) Crosslinking of the Conductive Layer 2

During this step ii, crosslinking of the conductive layer 2 is performed, for example, by vulcanization at a temperature of 150° C. for a time of 5 minutes.

The conductive layer 2 may comprise each of the constituents (a), (b), (c) and (d) in the following weight proportions (for a total of 100% by weight):
(e) from 10% to 65% by weight of at least one optionally substituted polythiophene conductive polymer,
(f) from 20% to 85% by weight of at least one adhesive polymer or adhesive copolymer,
(g) from 5% to 40% by weight of metal nanofilaments 3, and
(h) from 0% to 15% by weight of at least one dissolution of additional polymer.

The following experimental results show values obtained by a multilayer conductive transparent electrode according to the invention, for essential parameters such as the transmittance at a wavelength of 550 nm T₅₅₀, the mean transmittance Tₘₑₐₙ, the surface electrical resistance R, the adhesion of the conductive layer 2 to the substrate layer 1 and also the presence or absence of optical defects.

These results are placed in relation with values obtained for multilayer conductive transparent electrodes derived from a counterexample according to the prior art detailed hereinbelow.

### 1) MEASUREMENT METHODOLOGY

### Measurement of the Total Transmittance

The total transmittance, i.e. the light intensity crossing the film over the visible spectrum, is measured on 50×50 mm specimens using a Perkin Elmer Lambda 35© spectrophotometer equipped with an integration sphere on a UV-visible spectrum [300 nm-900 nm].

Two transmittance values are recorded:

the transmittance value at 550 nm T₅₅₀, and

the mean transmittance value Tₘₑₐₙ over the entire visible spectrum, this value corresponding to the mean value of the transmittances over the visible spectrum. This value is measured every 10 nm.

### Measurement of the Surface Electrical Resistance

The surface electrical resistance (in Ω/□) may be defined by the following formula:

$$R = \frac{ρ}{e} = \frac{1}{a \cdot e}$$

e: thickness of the conductive layer (in cm),

σ: conductivity of the layer (in S/cm) (σ=1/ρ),

ρ: resistivity of the layer (in Ω·cm).

The surface electrical resistance is measured on 20×20 mm specimens using a Keithley 2400 SourceMeter© ohmmeter and on two points to take the measurements. Gold contacts are first deposited on the electrode by CVD, in order to facilitate the measurements.

### Evaluation of the Presence of Defects

The evaluation of the presence of defects in the transparent electrode is performed on 50×50 mm specimens using an Olympus BX51© optical microscope at magnification (×100, ×200, ×400). Each specimen is observed by microscope at the different magnifications in its entirety. All the specimens not having defects greater than 5 μm are considered as being valid.

### Evaluation of the Adhesion of the Electrode to the Substrate

The evaluation of the adhesion of the electrode to the substrate is performed on 50×50 mm specimens using an ASTMD3359© adhesion test. The principle of this test consists in producing a grid by making parallel and perpendicular incisions in the coating using a disc-cutter scratching tool. The incisions must penetrate down to the substrate. Next, pressure-sensitive adhesive tape is applied onto the grid. The tape is then removed rapidly. All the specimens not showing any peeling are considered as being valid.

### 2) COMPOSITION OF THE EXAMPLES

### Key

| | |
|---|---|
| DMSO | Dimethyl sulfoxide |
| PEDOT:PSS | poly(3,4-ethylenedioxythiophene)- |
| | poly(styrenesulfonate) |
| Emultex 378 © | Polyvinyl acetate |
| Revacryl 272 © | Acrylonitrile - acrylic ester copolymer |
| Synthomer 5130 © | Acrylonitrile - butadiene copolymer |
| PVP | Polyvinylpyrrolidone |
| IPA | Isopropanol |

### Example A

0.8 g of a dispersion of silver nanofilaments at a concentration of 0.19% by weight in isopropanol (IPA) is scraper-coated onto a glass substrate to form a percolating network of silver nanofilaments.

10 g of DMSO are added to 5 g of PEDOT:PSS Clevios PH1000© containing 1.2% dry extract. The mixture is stirred using a magnetic stirrer at 600 rpm. After stirring for 10 minutes, 0.6 g of Emultex 378© (dry extract 45%, Tg=40° C.) are added to the solution and stirred for 30 minutes.

The mixture obtained is then scraper-coated onto the percolating network of silver nanofilaments. This network is vulcanized at 150° C. for a time of 5 minutes.

### Example B

0.8 g of a dispersion of silver nanofilaments at a concentration of 0.19% by weight in IPA is scraper-coated onto a flexible substrate (PET, PEN) to form a percolating network of silver nanofilaments.

10 g of DMSO are added to 30 mg of PVP (diluted to 20% in deionized water) and then stirred for 10 minutes using a magnetic stirrer at 600 rpm. 5 g of PEDOT:PSS Clevios PH1000© containing 1.2% dry extract are then added to the preceding mixture. After stirring for a further 10 minutes, 0.6 g of Revacryl 272© (dry extract 45%, Tg=−30° C.) are added to the solution and stirred for 30 minutes.

The mixture obtained is then scraper-coated onto the percolating network of silver nanofilaments. This network is vulcanized at 150° C. for a time of 5 minutes.

### Example C

20 g of DMSO are added to 20 mg of PVP (diluted to 20% in deionized water) and then stirred for 10 minutes using a magnetic stirrer at 600 rpm. 5 g of PEDOT:PSS Clevios PH1000© containing 1.2% dry extract are then added to the preceding mixture. After a further 10 minutes of stirring, 0.6 g of Emultex 378© (dry extract 45%, Tg=40° C.) and 4 g of a dispersion of silver nanofilaments at a concentration of 2.48% by weight in IPA are added to the solution and stirred for 30 minutes.

The mixture obtained is then scraper-coated onto a glass substrate. The deposit is then vulcanized at 150° C. for a time of 5 minutes.

### Example D

0.6 g of a dispersion of silver nanofilaments at a concentration of 0.19% by weight in IPA are scraper-coated onto a glass substrate to form a percolating network of silver nanofilaments.

10 g of DMSO are added to 30 mg of PVP (diluted to 20% in deionized water) and then stirred for 10 minutes using a magnetic stirrer at 600 rpm. 5 g of PEDOT:PSS Clevios PH1000© containing 12% dry extract are then added to the preceding mixture. After stirring for a further 10 minutes, 0.6 g of Revacryl 272© (dry extract 45%, Tg=−30° C.) are added to the solution and stirred for 30 minutes.

The mixture obtained is then scraper-coated onto the percolating network of silver nanofilaments. This network is vulcanized at 150° C. for a time of 5 minutes.

Counterexample according to the prior art:

2 g of nitrile rubber (NBR) Synthomer 5130©, which is self-crosslinking and prediluted to 15% with distilled water, are deposited on a flexible substrate (PET, PEN) using a spincoater according to the following parameters: acceleration 200 rpm/s, speed 2000 rpm for 100 s. The latex film is then vulcanized at 150° C. for 5 minutes in an oven.

2 g of dispersion of silver nanofilaments at a concentration of 0.16% by weight in ethanol are then deposited on the layer of vulcanized latex by spin coating (acceleration 500 rpm·s, speed: 5000 rpm, time: 100 s). This operation is repeated 6 times (6 layers of sliver nanofilaments) to form a percolating network of silver nanofilaments.

8.5 mg of MWNTs Graphistrength C100© carbon nanotubes are dispersed in 14.17 g of a dispersion of PEDOT:PSS Clevios PH1000© and in 17 g of DMSO, using a high-shear mixer (Silverson L5M©) at a speed of 800 revolutions/minute for 2 hours.

31.1 g of the dispersion of carbon nanotubes prepared previously are added to 3.76 g of Synthomer© in aqueous suspension. The mixture is then stirred using a magnetic stirrer for 30 minutes.

The mixture obtained is then filtered using a stainless steel grate (Ø=50 μm), so as to remove the dusts and large aggregates of poorly dispersed carbon nanotubes.

The mixture is then applied to the percolating network of silver nanofilaments using a spincoater (acceleration 500 rpm·s, speed: 5000 rpm, time: 100 s). This network is vulcanized at 150° C. for 5 minutes.

### RESULTS

| | Example A | Example B | Example C | Example D | Counterexample |
|---|---|---|---|---|---|
| Transmittance | 82.6 | 83.2 | 81.8 | 88.5 | 82.1 |
| at | | | | | |
| 550 nm (%) | | | | | |
| Mean | 81.3 | 82.0 | 80.0 | 86 | 80.2 |
| transmittance | | | | | |
| (%) | | | | | |
| Surface | 12 | 16 | 22 | 30 | 38 |
| resistance | | | | | |
| (Ω/□) | | | | | |
| Adhesion to | Validated | Validated | Validated | Validated | Validated |
| the substrate | | | | | |
| Absence of | Validated | Validated | Validated | Validated | Not validated |
| optical | | | | | |
| defects | | | | | |

The presence of an adhesive polymer or adhesive copolymer (b) directly in the conductive layer 2 allows direct contact and direct adhesion of the latter to the substrate layer 1 without it being necessary to apply beforehand an additional adhesion layer onto said substrate layer 1. This then allows high transmittance. Furthermore, the composition of the conductive layer 2 allows low surface resistance, and does so without the presence of elements “doping” the conductivity, for instance carbon nanotubes used in the prior art.

This multilayer conductive transparent electrode thus has high transmittance, a low surface electrical resistance, for a reduced cost since the composition is simpler and requires fewer manufacturing steps.

1. A multilayer conductive transparent electrode having first and second opposing surfaces, the multilayer conductive transparent electrode comprising:
a substrate layer having a second surface corresponding to the second surface of the multilayer conductive transparent electrode and a first opposing surface;
a conductive layer having a first surface corresponding to the first surface of the multilayer conductive transparent electrode and a second opposing surface, wherein the second surface of the conductive layer is disposed over and in direct contact with the first surface of the substrate layer, the conductive layer comprising:
at least one polythiophene conductive polymer,
a percolating network of metal nanofilaments, and
at least one of an hydrophobic adhesive polymer and an adhesive copolymer.

2. The multilayer conductive transparent electrode as claimed in claim 1 wherein the conductive layer further comprises at least one additional polymer.

3. The multilayer conductive transparent electrode as claimed in claim 2 wherein the at least one additional polymer is polyvinylpyrrolidone.

4. The multilayer conductive transparent electrode as claimed in claim 1 wherein the multilayer conductive transparent electrode has a mean transmittance over wavelengths in visible spectrum of substantially greater than or equal to about seventy-five percent.

5. The multilayer conductive transparent electrode as claimed in claim 1 wherein at least one of the first and second surfaces of the multilayer conductive transparent electrode has a surface resistance of less than one-hundred ohms per square (Ω/□).

6. The multilayer conductive transparent electrode as claimed in claim 1 wherein the substrate layer comprises a material that includes at least one of glass and transparent flexible polymers.

7. The multilayer conductive transparent electrode as claimed in claim 1 wherein the metal nanofilaments are nanofilaments of noble metals.

8. The multilayer conductive transparent electrode as claimed in claim 1 wherein the metal nanofilaments are nanofilaments of non-noble metals.

9. The multilayer conductive transparent electrode as claimed in claim 1 wherein the adhesive polymer and adhesive copolymer comprises a material that includes at least one of polyvinyl acetate polymers and acrylonitrile-acrylic ester copolymers.

10. A process for manufacturing a multilayer conductive transparent electrode having first and second opposing surfaces, the process comprising:
providing a substrate layer having a second surface corresponding to the second surface of the multilayer conductive transparent electrode and a first opposing surface;
a conductive layer having a first surface corresponding to the first surface of the multilayer conductive transparent electrode and a second opposing surface, and disposing the second surface of the conductive layer directly onto the first surface of the substrate layer, said conductive layer comprising:
at least one polythiophene conductive polymer,
a percolating network of metal nanofilaments, and
at least one of an hydrophobic adhesive polymer and an adhesive copolymer; and
crosslinking the conductive layer to form a multilayer conductive transparent electrode comprising at least the substrate layer and the conductive layer.

11. The process for manufacturing a multilayer conductive transparent electrode as claimed in claim 10 wherein preparing a conductive layer having a first surface corresponding to the first surface of the multilayer conductive transparent electrode and a second opposing surface, and disposing the second surface of the conductive layer over the first surface of the substrate layer comprises:
preparing a conductive layer composition, the conductive layer composition comprising:
a dispersion or suspension of at least one polythiophene conductive polymer, and
at least one of an hydrophobic adhesive polymer and an adhesive copolymer,
adding a suspension of metal nanofilaments to the conductive layer composition,
disposing the conductive layer composition including the metal nanofilaments over the second surface of the substrate layer, and
drying the conductive layer composition to form a conductive layer having a first surface corresponding to the first surface of the multilayer conductive transparent electrode and a second opposing surface.

12. The process for manufacturing a multilayer conductive transparent electrode as claimed in claim 10 wherein preparing a conductive layer having a first surface corresponding to the first surface of the multilayer conductive transparent electrode and a second opposing surface, and disposing the second surface of the conductive layer over the first surface of the substrate layer comprises:
preparing a conductive layer composition, the conductive layer composition comprising:
a dispersion or suspension of at least one polythiophene conductive polymer, and
at least one of an hydrophobic adhesive polymer and an adhesive copolymer;
disposing a suspension of metal nanofilaments over the second surface of the substrate layer so as to form a percolating network of metal nanofilaments on the second surface of the substrate layer,
disposing the conductive layer composition over the percolating network of metal nanofilaments, and
drying the conductive layer composition to form a conductive layer having a first surface corresponding to the first surface of the multilayer conductive transparent electrode and a second opposing surface.

13. The process for manufacturing a multilayer conductive transparent electrode as claimed in claim 12 wherein the conductive layer composition further comprises at least one additional polymer.

14. The process for manufacturing a multilayer conductive transparent electrode as claimed in claim 13 wherein the additional polymer is polyvinylpyrrolidone.

15. The process for manufacturing a multilayer conductive transparent electrode as claimed in claim 10 wherein the substrate layer comprises a material that includes at least one of glass and transparent flexible polymers.

16. The process for manufacturing a multilayer conductive transparent electrode as claimed in claim 10 wherein the metal nanofilaments are nanofilaments of noble metals.

17. The process for manufacturing a multilayer conductive transparent electrode as claimed in claim 10 wherein the metal nanofilaments are nanofilaments of non-noble metals.

18. The process for manufacturing a multilayer conductive transparent electrode as claimed in claim 10 wherein the adhesive polymer or adhesive copolymer comprises a material that includes at least one of polyvinyl acetate polymers and acrylonitrile-acrylic ester copolymers.
